(19) United States
(12) Patent Application Publication
(10) Pub. No.: US 2004/0244684 A1
(43) Pub. Date: Dec. 9, 2004

(54) System and method of deposition of magnetic multilayer film, method of evaluation of film deposition, and method of control of film deposition

(75) Inventors: Takaaki Tsunoda, Santa Clara, CA (US); Shigeru Mizuno, Tokyo (JP)

Correspondence Address: BURNS DOANE SWECKER & MATHIS L L P, POST OFFICE BOX 1404, ALEXANDRIA, VA, 22313-1404, US

(73) Assignee: Anelva Corporation

(21) Appl. No.: 10/764,550

(22) Filed: Jan. 27, 2004

(30) Foreign Application Priority Data
Jan. 28, 2003 (JP) JP2003-18935

(51) Int. Cl. C23C 16/00

(52) U.S. Cl. 118/715; 118/712

(57) ABSTRACT

A magnetic multilayer film deposition system having a plurality of treatment chambers for depositing a multilayer film including a plurality of magnetic films on a substrate, a conveyance system for conveying the substrate in a state shielded from the atmosphere, a metal film treatment chamber, a treatment system having treating metal film included in the multilayer film in the treatment chamber, an optical measurement system for optically evaluating the surface state of the metal film, and a control system for controlling the operation of the treatment system based on a measurement signal output from this optical measurement system, wherein when depositing a multilayer film on a substrate in the film deposition system, it is possible to manage the surface state of the metal film during the treatment process of the metal film and possible to treat the metal film precisely.

### CROSS-REFERENCE TO RELATED APPLICATIONS

The present application claims the benefit of Japanese Patent Application No. JP2003-18935, filed in Japan on Jan. 28, 2003, the entire contents of which are hereby incorporated herein by reference.

### BACKGROUND OF THE INVENTION

1. Field of the Invention

The present invention relates to a system and method for deposition of a magnetic multilayer film, a method of evaluation of film deposition, and a method of control of film deposition. One aspect of the invention relates to management of the surface characteristics of a film during the process of deposition of a multilayer film for depositing a metal oxide film while evaluating the surface state or for successively stacking films or oxide films of the same continuously in an environment shielded from the atmosphere during the production of a semiconductor device and electronic component.

2. Description of the Related Art

In recent years, various techniques have been developed in magnetic recording media and magnetic heads for stabilizing and improving the magnetic recording density of HDDs. In particular, in recent years, tunnel magnetoresistance thin film (TMR) heads have been employed as devices with large MR ratios. Further, magnetic random access memories (MRAMs) having a TMR structure have been gathering attention as the next generation of semiconductor devices. The film depositing a TMR device is comprised of at least one magnetic layer above and below sandwiching an insulating film. Each of the magnetic films is individually deposited utilizing sputtering, while the insulating film is deposited by oxidation of a metal film. To produce a plurality of magnetic films continuously, it is necessary to continuously stack them on a substrate. The assignee of the present invention has proposed one such method of continuous stacking (Japanese Patent Publication (A) No. 2002-167661).

According to the method disclosed in Japanese Patent Publication (A) No. 2002-167661, magnetic films or nonmagnetic films are continuously deposited in a stacked state in for example three different film deposition chambers. Further, an Al film is deposited by an Al target arranged in for example one film deposition chamber, then that Al film is oxidized in an oxidation treatment chamber of a separately provided similar vacuum environment.

Note that as related art of the present invention, there is the method of rotating a member having a spheroid shape while depositing a film of a suitable thickness on its surface by sputtering by the method of monitoring the spectral characteristics of the film while by an optical system in real time while depositing the film (Japanese Patent Publication (A) No. 2002-30435). Further, a high sensitivity reflection infrared spectrum measurement method for quantitatively analyzing the state of orientation of molecules of the measured object at an interface between a substrate and measured object has been proposed (Japanese Patent Publication (A) No. 9-264848).

In the above TMR device, due to the need for reducing the contact resistance, the thickness of the insulating layer is made an extremely thin one of 1 nm. Smoothness and sufficient oxidation are required. The electrical characteristics of a TMR device are heavily influenced by the state of oxidation. With sufficient oxidation, a high MR ratio is obtained.

However, in a general conventional system, to determine whether an Al film has been completely oxidized or not, the only approach was to take a monitoring use substrate out from the film deposition system and measure its electrical and magnetic characteristics after processing the device in an atmospheric environment. Therefore, even if a problem arose in the middle of the series of processes for making a device such as a TMR device, there was no means for judging this until the final product stage and therefore massive product loss occurred before eliminating the problem.

### OBJECTS AND SUMMARY

An object of the present invention is to solve the above problem and provide a system for deposition of a magnetic multilayer film and method for deposition of a magnetic multilayer film which constantly manage the state of oxidation of a film and thereby oxidize the film precisely during the process of oxidation of film in a series of steps of production of a device using a metal oxide etc. as an insulating film. Another object of the present invention is to provide a method of evaluation of film deposition when oxidizing a metal film and a method of control of deposition of a metal oxide film.

The system and method of deposition of a magnetic multilayer film, method of evaluation of film deposition, and method of control of film deposition according to the present invention are configured as follows to achieve the above objects.

According to a first aspect of the present invention, there is provided a magnetic multilayer film deposition system having a plurality of treatment chambers for depositing a multilayer film including a plurality of magnetic films on a substrate, a conveyance mechanism for conveying the substrate on which a film is deposited in a state shielded from the atmosphere, and a metal film treatment chamber, provided with a treatment apparatus for treating the metal film included in the multilayer film in the metal film treatment chamber, an optical measurement device for optically evaluating the surface state etc. of the metal film, and a controller for controlling the operation of the treatment devices based on a measurement signal output from the optical measurement device. Due to this, when depositing a multilayer film on a substrate in the film deposition system, it is possible to manage the surface state etc. of the metal film during the treatment of the metal film or after treatment without exposing the substrate to the atmosphere and possible to suitably manage the metal film. Further, it is possible to continuously treat the thus deposited metal film without exposure to the atmosphere and deposit other necessary films on the same.

Preferably, the optical measurement device is a reflection type infrared spectrophotometer. This optical measurement device is comprised of a light source for generating infrared light provided at the outside of the metal film treatment chamber, an incident window for guiding the infrared light to the surface of the metal film of the substrate arranged in the treatment chamber, a reflected light window for taking out measurement light passing the surface of the metal film to the outside of the treatment chamber, a detector for detecting the measurement light, and a processor for determining the surface state of the film from a detected signal. Due to the above configuration, it is possible to detect a part of a sample where the surface state etc. of an extremely thin film is not destroyed and is arranged in a vacuum from the atmospheric side, optimally controlling the treatment by feeding back the detected information to the system performing the treatment, and thereby manage the treatment process.

More preferably, the measurement light is light arising at the interface between a treated part and nontreated part of the metal film. It is possible to obtain measurement light based on the state of treatment of the metal film.

Alternatively, the measurement light is infrared light reflected by the relationship with another film positioned at the back surface of the metal film. Since this is a system for depositing a multilayer film on a substrate, it is possible to obtain measurement light without providing a special reflector at the back surface of the metal film to be treated.

Preferably, the plurality of treatment chambers and the metal film treatment chamber are arranged around the conveyance chamber provided with the conveyor, the substrate is moved in a state shielded from the atmosphere, and the evaluation process of the metal film in the metal film treatment chamber is performed in a vacuum. Due to this configuration, it is possible to perform the evaluation according to the state of treatment of the metal film without exposure to the atmosphere and possible to treat a predetermined metal film precisely while evaluating the surface state of the substrate while maintaining the film depositing process.

Preferably, the treatment performed in the metal film treatment chamber is an oxidation treatment. Due to this configuration, it is possible to manage a suitable state of oxidation of an extremely thin Al oxide film at a device such as a TMR device. Further, it is possible to detect the state of oxidation while oxidizing the film and then end the oxidation step.

According to a second aspect of the present invention, there is provided a method of deposition of a magnetic multilayer film for depositing a multilayer film including a plurality of magnetic films on a substrate, wherein metal film included in the multilayer film is optimally treated while optically measuring and evaluating the surface state etc. of the metal film at a stage in the middle of film deposition and in a state shielded from the atmosphere.

Preferably, the surface state etc. of the metal film is measured and evaluated based on detection of the state of oxidation of the metal film.

According to a third aspect of the present invention, there is provided a method of evaluating a deposition of a metal film on a substrate, the method comprising treating the metal film in a state shielded from the atmosphere and evaluating the state of progress of treatment at the metal film while optically measuring the relationship between a treated part and nontreated part of the metal film.

Preferably, the treatment state of the metal film is evaluated based on detection of the state of oxidation of the metal film.

Preferably, the metal film is made of Al and the increase in the oxidized part is evaluated from the difference in absorption strength of a peak position (Al—O) of an oxidized part expressed by oxidation based on the Al before oxidation for light of a predetermined frequency.

According to a fourth aspect of the present invention, there is provided a method of control of deposition of a metal film on a substrate comprising oxidizing the metal film in a state shielded from the atmosphere, optically measuring the relationship between an oxidized part and nonoxidized part of the metal film, and evaluating the state of progress of oxidation at the metal film.

As clear from the above explanation, it is possible to provide a system for deposition of a multilayer film including a magnetic film of a magnetic head comprised of a TMR device, MRAM, etc. which can perform oxidation treatment while managing the state of oxidation of the Al film deposited by a film deposition chamber as an insulating film of the TMR device and which can form good quality devices with a good yield while maintaining the vacuum environment without exposing substrates to the atmosphere.

### BRIEF DESCRIPTION OF THE DRAWINGS

These and other objects and features of the present invention will become clearer from the following description of the preferred embodiments given with reference to the attached drawings, wherein:

FIG. 1 is a plan view schematically showing the overall configuration of a typical embodiment of a multilayer film deposition system according to the present invention;

FIG. 2 is a vertical sectional view of the schematic configuration of an embodiment of an oxidation treatment system included in the multilayer film deposition system according to the present invention (oxidation treatment chamber);

FIGS. 3A to 3B are views of examples of the structure of a magnetic multilayer film;

FIG. 4 is a view of the relationship between the absorption strength of a band near 970 cm⁻¹ (Al—O stretching vibration) and Al film oxidation time; and

FIG. 5 is a view of the relationship between a peak position of an Al—O stretching vibration absorption band and Al film oxidation time.

### DESCRIPTION OF THE PREFERRED EMBODIMENTS

Below, preferred embodiments of the present invention will be explained with reference to the attached drawings.

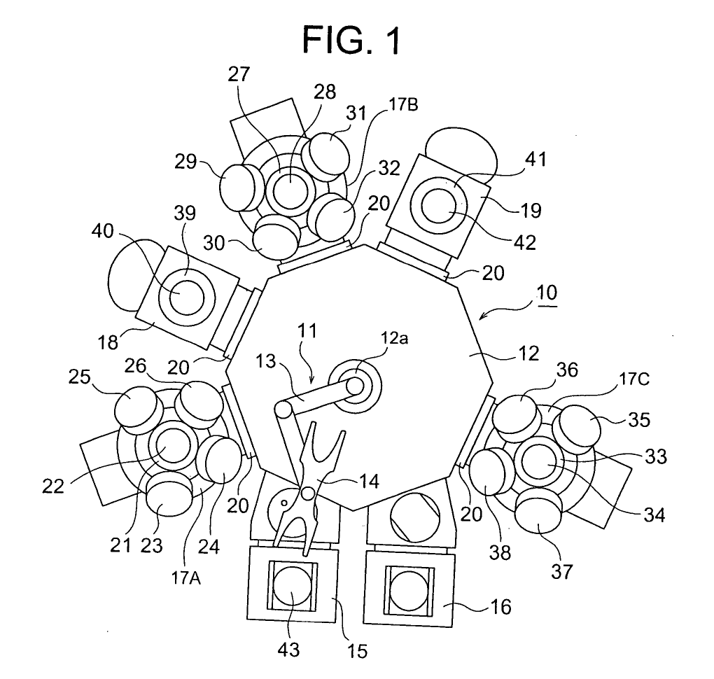

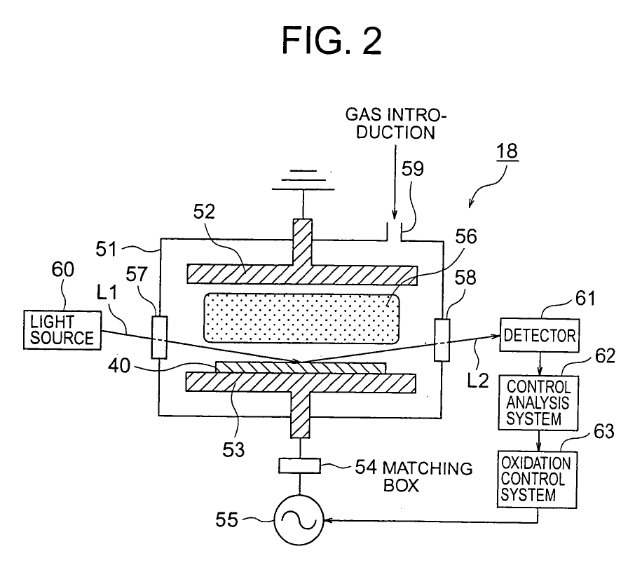

First, the configuration of the system according to an embodiment of the present invention will be explained with reference to FIG. 1 and FIG. 2. The system shown in FIG. 1 is a system for deposition of a multilayer film including a plurality of magnetic films. The system shown in FIG. 2 is a metal film treatment system performing oxidation treatment and corresponds to the oxidation treatment chamber included in a multilayer film deposition system.

The magnetic multilayer film deposition system 10 shown in FIG. 1 is a cluster type system provided with a plurality of film deposition chambers. In this system, a conveyance chamber 12 provided with a robot conveyor 11 is positioned at the center. The robot conveyor 11 is provided with an arm 13 able to extend and contract in the radial direction and a hand 14 for carrying the substrate. The base end of the arm 13 is rotatably attached to a center 12a of the conveyance chamber 12. The conveyance chamber 12 of the magnetic multilayer film deposition system 10 is provided with two load/unload chambers 15 and 16 which load/unload substrates 43. These load/unload chambers 15 and 16 are alternately used to enable deposition of a multilayer film with good productivity.

In the above magnetic multilayer film deposition system 10, the conveyance chamber 12 is provided around it with for example three film deposition chambers 17A, 17B, and 17C, one oxidation treatment chamber 18, and one cleaning chamber 19. In the oxidation treatment chamber 18, for example Al film (in general a metal film) is oxidized to deposit an oxide film on its surface. Between each two chambers is provided a gate valve 20 separating the two chambers and able to open and close in accordance with need. Note that each chamber is provided with a not shown vacuum evacuation mechanism, gas introduction mechanism, and power feed mechanism.

At each of the film deposition chambers 17A, 17B, and 17C of the magnetic multilayer film deposition system 10, magnetic film is deposited on the substrate by sputtering. For example, the ceilings of the film deposition chambers 17A, 17B, and 17C are provided with four targets (23, 24, 25, and 26; 29, 30, 31, and 32; and 35, 36, 37, and 38) arranged on suitable circles. Substrates 22, 28, and 34 are arranged on substrate holders 21, 27, and 33 positioned below them coaxially with the same circles.

The plurality of targets are provided at inclines so as to suitably face the substrates in order to efficiently deposit magnetic films of suitable compositions, but it is also possible to provide them in states parallel to the substrate surfaces. Further, the plurality of targets and substrates are arranged so as to be able relatively rotate. As such a configuration, for example, it is possible to use one based on the rotating cathode mechanism disclosed in Japanese Patent Publication (A) No. 2002-088471 according to a patent application filed previously by the assignee. For example, the film deposition chamber 17B is provided with an Al target and other magnetic film targets based on the above arrangement. As a result, a multilayer film having a multilayer film structure explained later is deposited on the substrate.

In the film deposition chambers 17A, 17B, and 17C, metal films are successively deposited in accordance with need, then the substrates 22, 28, and 34 are conveyed to the oxidation treatment chamber 18 provided with the oxidation mechanism where the metal films are oxidized. In the example shown in FIG. 1, a substrate 40 is carried on a substrate holder 39 in the oxidation treatment chamber 18.

In the cleaning chamber 19 as well, a substrate 42 is carried on the substrate holder 41.

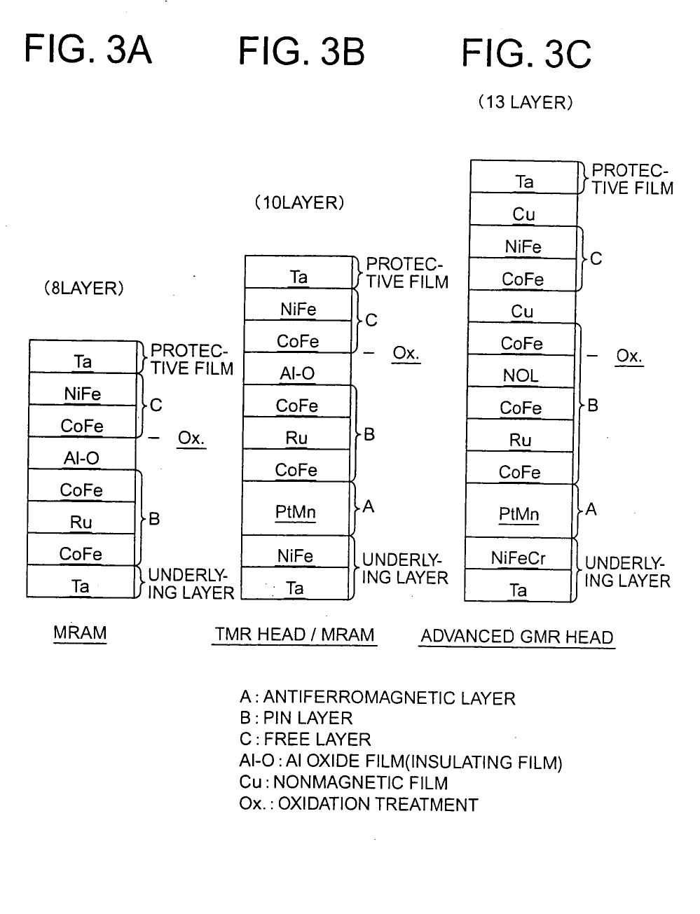

FIGS. 3A to 3B show examples of magnetic multilayer film structures. FIG. 3A shows an example of the multilayer structure of an eight-layer MRAM, FIG. 3B shows an example of the multilayer structure of a 10-layer TMR head/MRAM, and FIG. 3C shows an example of the multilayer structure of a 13-layer advanced GMR head. For example, after deposition of the Al film in the example of FIG. 3B and after deposition of the CoFe film of the B configuration in the example of FIG. 3C, the robot controller 11 introduces the substrate into the oxidation treatment chamber 18 where it is oxidized. As a result, a Al—O film is formed in the example of FIG. 3B and a nano oxide layer (NOL) is made by oxidizing the CoFe film in the example of FIG. 3C.

First, a mechanism for management of the state of oxidation of an Al film will be explained.

In the oxidation treatment chamber 18, a surface chemical reaction is performed for oxidizing the Al film. This surface chemical reaction is for example plasma oxidation, ozone oxidation, ultraviolet ray ozone oxidation, radical oxidation, etc. Among these, the example of plasma oxidation will be explained.

The oxidation treatment chamber 18 shown in FIG. 2 is provided with a mechanism for plasma oxidation. This oxidation treatment chamber 18 is formed as a vacuum chamber 51 overall. Inside this vacuum chamber 51 are provided a top electrode 52 and a bottom electrode 53. The top electrode 52 is fixed to the ceiling of the vacuum chamber 51 via an insulator (not shown), while the bottom electrode 53 is fixed to the bottom of the vacuum chamber 51 via an insulator (not shown). The bottom electrode 53 corresponds to the substrate holder 39 shown in FIG. 1.

As the electrical connections, the top electrode 52 is connected to the ground, while the bottom electrode 53 is connected to an RF power source (high frequency power source) 55 through a matching box 54. The bottom electrode 53 carries the substrate 40. When the plasma conditions stand, plasma 56 is produced in the space between the top electrode 52 and the bottom electrode 53. Further, an infrared light incident window 57 and a reflection light window 58 are provided in the wall of the vacuum chamber 51. Further, the ceiling of the vacuum chamber 51 is provided with a gas inlet 59 for introducing feedstock gas for producing the plasma.

At the outside of the oxidation treatment chamber 18 is provided an optical measurement device. This optical measurement device preferably is a Fourier transform infrared (FTIR) spectrophotometer using the high sensitivity reflection method utilizing infrared light. Outside of the infrared light incident window 57 is provided a light source 60 for outputting infrared light. The infrared light L1 output from the light source 60 passes through the incident window 57 and passes through the Al oxide film on the substrate 40 arranged in the oxidation treatment chamber 18 to reach the Al film or underlying CoFe film. The infrared light L1 incident at the multilayer film deposited on the substrate 40 is at first reflected at the Al film, thereafter at the interface of the Al oxide film (Al—O) and Al film along with the progress of oxidation of the Al film, and finally at the surface of the CoFe film.

The infrared light L2 reflected in the above way is taken from the reflection light window 58 to the outside of the oxidation treatment chamber 18 as measurement light and detected by a detector 61. The signal concerning the reflected light L2 based on the infrared light L1, which is detected by the detector 61, is further analyzed by a control analysis system 62. This control analysis system 62 calculates an absorption strength, an absorption band position, and other data concerning the reflected light L2 of the infrared light L1 due to the state of the Al oxide (Al—O) film. The data is sent to an oxidation control system 63. The oxidation control system 63 optimally controls the output of the RF power source 55 for optimal oxidation by the oxidation treatment of the Al film of the multilayer film on the substrate 40.

In the above, when evaluating the state of oxidation of the Al film on the substrate 40 by the FTIR technique in order to control the oxidation at the Al film, the following steps are performed. When oxidation of the Al film progresses and the Al oxidation film (Al—O film) is gradually formed, a peak value of the absorption strength about the Al oxide (Al—O) film is calculated from the difference between the absorption strength value concerning the Al—O part and the standard absorption strength value concerning the Al film part near about 970 cm⁻¹, and further the state of oxidation at the Al film is controlled by evaluating the increase state in the above peak value. In this way, when oxidation progresses at the Al film, in order to evaluate the state of the oxidation, the peak value of the absorption strength at the Al—O part, which is being oxidized, is used in comparison with the absorption strength value at the Al film part as a standard value before performing the oxidation.

By controlling the oxidation of the Al film, evaluation is possible even without taking the film out into the atmosphere. Therefore, it is possible to deposit an optimal oxide film. This is preferable when depositing a single layer of oxide film on a substrate or when depositing an oxide film included in a multilayer film. In particular, when depositing the multilayer film on the substrate, since it is not necessary to take the substrate out into the atmosphere, there is the advantage that it is possible to continuously deposit other necessary films on top to form the final film structure.

In the above control of oxidation of Al film, where to stop the oxidation treatment is a problem. In general, it is stopped by the following method.

Step 1: Before performing the oxidation, the absorption strength of the Al film at a place which the peak of absorption strength of the Al—O film will be appeared is detected. This detected absorption strength value is used as a standard value.

Step 2: The peak value of the absorption strength of the Al—O film during the oxidation treatment is detected. At this time, the absorption strength at a specific wave number due to oxidation of the metal is detected.

Step 3: The difference value between the standard value of the Al film and the peak value of the Al—O film is obtained by calculating the difference between the both values. This is based on the fact that the same material indicates absorption strength proportional to the existing amount thereof. (Lambert-Beer law). However, since the peak position as to the Al—O film shifts to the side of a lower wave number with the advance of the oxidation, it is necessary to detect a light level for the absorption of the peak in a certain range of the absorption wave number region in the vicinity of a specific wave number due to the metal oxidation. The differences in strength of the some peaks of the Al—O film are compared and managed as numerical values. Further, the peak value may be successively plotted along with the elapse of time to draw a curve of change for management from the viewpoint of the inclination of the curve of change.

Step 4: The above step 1 and step 2 are repeated successively to compare the previous detected amount and new detected amount. When the amount of increase falls below a certain value, the state of oxidation is evaluated as optimal and the oxidation treatment is stopped. As one example, the system is set to stop the oxidation treatment when 100% or 95% of the Al film has been oxidized. Such a value depends on the later annealing or other processes. Therefore, whether to completely oxidize the film or stop just before complete oxidation is dependent on a design condition.

The above method of control of oxidation of an Al film etc. is effective for calculation of the state of oxidation in advance and is effective in a production line performing oxidation by these set conditions.

In the above configuration of an oxidation treatment chamber 18, for example, the material of the infrared light incident window 57 and the reflection light window 58 is for example Ge (germanium) having a transmission region in accordance with the detection light. The light source 60 is a silicon carbide sintered body and He—Ne laser for the correction of the wavelength of the light source light. The detector 61 is an MCT (Hg—Cd—Te) detector.

Further, the high sensitivity reflection infrared spectrum measurement method, as disclosed for example in Japanese Patent Publication (A) No. 6-241992 or Japanese Patent Publication (A) No. 9-264848, is used in numerous fields as a method for analysis which arranges a metal reflector at the back surface of a measured object to reflect the incident infrared light and thereby obtain information such as the thickness of the measured object, the type of chemical bond, the functional groups, etc.

In the above high sensitivity reflection infrared spectrum measurement method, as explained above, a metal reflector by which infrared light irradiated to the surface of the substrate is reflected at the back surface of the measured object, for example, one reflecting infrared light by a reflectance of at least 20% in the above known publications, is preferable. Gold, silver, copper, aluminum, etc. is necessary.

For this, in the configuration of the present embodiment of the present invention, a metal multilayer film having a CoFe film as its topmost layer is deposited at the bottom of the film desired to be oxidized as shown in FIG. 3. Further, since the multilayer film structure is deposited by continuous stacking in a state with a good uniformity of thickness, the characterizing feature of the embodiment of the multilayer film deposition system according to the present invention, the multilayer film surfaces formed (interfaces) are extremely smooth. Therefore, in the present embodiment, in order to measure the reflection infrared spectrum, there is no need to arrange a smooth metal film at the back surface of the measured object required. It is possible to make measurements in the state of the substrate with the multilayer film deposited as it is.

Next, the configuration of a multilayer film including magnetic film will be explained with reference to FIG. 3. In the present embodiment, the sample part measured based on the infrared light reflection action is the Al oxide film (Al₂O₃ film) or CoFe oxide film in the middle of deposition of the multilayer film including a plurality of magnetic films deposited on the substrate. An example of an Al film will be explained. As shown in FIGS. 3A and 3B, an MRAM or TMR head is comprised of a multilayer film including a plurality of magnetic films. “A” indicates an antiferromagnetic layer, “B” a multilayer magnetic layer (pin layer), “Al—O” an Al oxide film, “C” a multilayer magnetic layer (free layer), and “Ta” a protective film. Each layer is comprised of an extremely thin film of several nm. “Ox” shows oxidation treatment. As shown in FIG. 3, the structure B and structure C are isolated from each other by an insulating layer comprised of an Al oxide film of about 1 nm.

W. Zhu et al. (Appl. Phys. Lett. 78, 3103 (2001)) publishes the results of evaluation of the oxidation of an Al film on Co required for high MR ratio magnetic tunneling junctions (MTJ) by Fourier transform infrared (FTIR) spectroscopy. The inventors experimented with similar evaluation in the middle of depositing the multilayer film structure in a vacuum system and obtained good results. The method used is shown below:

Oxidation treatment method: Oxygen plasma oxidation Conditions: RF 20W, Ar 20 sccm, O₂ 2 sccm

Oxidation time: 20 sec, 60 sec, 80 sec, 180 sec

Sample

| Sample | Al oxidation time |
|---|---|
| Sample 1 | 0 sec |
| Sample 2 | 20 sec |
| Sample 3 | 60 sec |
| Sample 4 | 80 sec |
| Sample 5 | 180 sec |

Sample (structure): Si substrate/CoFe (2 nm)/Al (1.2 nm)

Measurement method: Fourier transform type infrared spectroscopy

Measurement technique: High sensitivity reflection

Resolution: 8 cm⁻¹

Cumulative number: 256

Measurement range: 4000 to 700 cm⁻¹

Detector: MCT detector

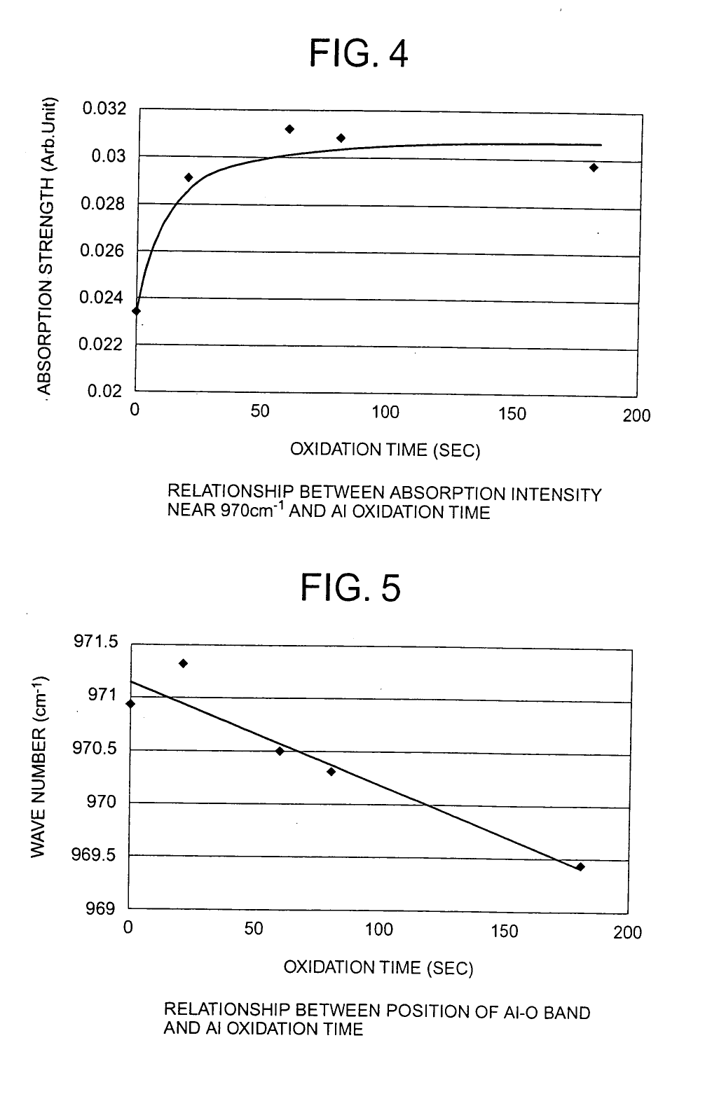

FIG. 4 is a graph of the relationship between the absorption intensity near 970 cm⁻¹ considered to be absorption by Al₂O₃ (Al—O stretching vibration) and Al film oxidation time. In FIG. 4, the abscissa indicates the oxidation time (sec), while the ordinate indicates the absorption strength (Arb. Unit: any unit). Further, FIG. 5 is a graph of the relationship between the peak position of the absorption band and the Al film oxidation time. In FIG. 5, the abscissa indicates the oxidation time (sec), while the ordinate indicates the wave number (cm⁻¹).

In FIG. 4, it is learned that the longer the oxidation time, the stronger the Al—O stretching vibration strength and the closer to a constant value. Further, in FIG. 5, it is learned that the longer the oxidation time, the closer to the low wave number side the peak position is shifted to. According to the above W. Zhu et al., it is reported that as the oxidation time becomes longer, the thickness of the oxide layer becomes greater and the Al—O stretching vibration peak position shifts more to the low wave number direction. The current experiment exhibited a similar trend. The above results evaluated the state of oxidation of the Al oxide film in the oxidation treatment chamber 18 after the end of plasma oxidation, but similar evaluation is possible even during the oxidation treatment.

With oxygen plasma, light of about 0.8 μm (777 nm) comprised mainly of oxygen atom radicals is produced, but infrared light used for measurement is generally 2.5 to 25 (m and is not interfered with. Further, in the FTIR method based on viewing the difference between the Al reflected light of the infrared light passing through and/or reflected at the plasma and the reflected light after absorption by Al—O, the relative difference between the two can be sufficiently obtained.

To form an actual device, to fix the magnetic layer (pin layer) of the structure B in FIG. 3B, annealing is necessary after depositing the multilayer film. For example, annealing is performed at 260° C. for about 5 hours. To obtain a good device through this process, in the case of a 1.2 nm Al film, if performing oxidation so that the strength of the Al—O stretching vibration at FIG. 4 becomes somewhat before saturation (60 to 80 sec), it is learned that a device having good magnetic properties is obtained. Note that this suitable state of oxidation differs according to the conditions during the process, so depends on the degree of oxidation or its production process.

Based on the above, according to the system or method according to the present embodiment, it is possible to detect the state of oxidation of Al film after oxidation or during oxidation by for example oxygen plasma etc. and possible to obtain an optimal Al oxide film by detecting the absorption position of Al—O or the absorption band of an oxidized compound by an underlying film of CoFe—O etc.

Note that the present invention is not limited to the above embodiments and enables management of not only the state of oxidation of an Al film, but also the state of oxidation of another metal. Further, the invention is not limited to a multilayer film and may also be applied to oxidation of a single layer of metal film. Further, it is not limited to oxidation and may also be applied for evaluation of a metal film treated by nitrification etc.

What is claimed is:

1. A magnetic multilayer film deposition system comprising a plurality of treatment chambers for depositing a multilayer film including a plurality of magnetic films on a substrate, a conveyor for conveying said substrate on which a film is deposited in a state shielded from the atmosphere, and a metal film treatment chamber, provided with:
a treatment device for treating the metal film included in said multilayer film in the metal film treatment chamber,
an optical measuring device for optically evaluating the state of said metal film, and
a controller for controlling the operation of said treatment device based on a measurement signal output from said optical measuring device.

2. The magnetic multilayer film deposition system as set forth in claim 1, wherein said optical measuring device is a reflection infrared spectrophotometer and is comprised of a light source for generating infrared light provided at the outside of the metal film treatment chamber, an incident window for guiding said infrared light to the surface of said metal film of said substrate arranged in said treatment chamber, a reflected light window for taking out measurement light passing the surface of said metal film to the outside of said treatment chamber, a detector for detecting said measurement light, and a processor for determining the state of the film from a detected signal.

3. The magnetic multilayer film deposition system as set forth in claim 2, wherein said measurement light is light arising at the interface between a treated part and nontreated part of said metal film.

4. The magnetic multilayer film deposition system as set forth in claim 2, wherein said measurement light is infrared light reflected by relation with another film positioned at the back surface of said metal film.

5. The magnetic multilayer film deposition system as set forth in claim 1, wherein said plurality of treatment chambers and said metal film treatment chamber are arranged around said conveyance chamber provided with said conveyor, said substrate is moved in a state shielded from the atmosphere, and the evaluation process of said metal film in said metal film treatment chamber is performed in a vacuum.

6. The magnetic multilayer film deposition system as set forth in claim 1, wherein the treatment performed in said metal film treatment chamber is oxidation treatment.

7. A method of deposition of a magnetic multilayer film for depositing a multilayer film including a plurality of magnetic films on a substrate, wherein metal film included in said multilayer film is optimally treated while optically measuring and evaluating the state of said metal film at a stage in the middle of film deposition and in a state shielded from the atmosphere.

8. The method of deposition of a magnetic multilayer film as set forth in claim 7, wherein the state of said metal film is measured and evaluated based on detection of the state of oxidation of said metal film.

9. A method of evaluation of deposition of a metal film on a substrate comprising treating said metal film in a state shielded from the atmosphere and evaluating the state of progress of treatment at said metal film while optically measuring the relationship between a treated part and nontreated part of said metal film.

10. The method of evaluation of film deposition as set forth in claim 9, wherein the treatment state of said metal film is evaluated based on detection of the state of oxidation of said metal film.

11. The method of evaluation of film deposition as set forth in claim 10, wherein said metal film is made of Al and the increase in said oxidized part is evaluated from the difference in absorption intensity of a peak position (Al—O) of an oxidized part expressed by oxidation based on the Al before oxidation for light of a predetermined frequency.

12. A method of control of deposition of a metal film on a substrate comprising oxidizing said metal film in a state shielded from the atmosphere, optically measuring the relationship between said oxidized part and nonoxidized parts of said metal film, and evaluating the state of progress of oxidation at said metal film.
